(19) United States
(12) Patent Application Publication
(10) Pub. No.: US 2012/0220101 A1
(43) Pub. Date: Aug. 30, 2012

(54) INTERNAL CONDUCTIVE LAYER

(75) Inventors: Ross Teggatz, McKinney, TX (US); Wayne Chen, Plano, TX (US); John Krick, Dallas, TX (US)

(73) Assignee: TRIUNE IP LLC, Richardson, TX (US)

(21) Appl. No.: 13/219,668

(22) Filed: Aug. 27, 2011

Related U.S. Application Data
(60) Provisional application No. 61/377,903, filed on Aug. 27, 2010.

(51) Int. Cl. H01L 21/762

(52) U.S. Cl. 438/455; 257/E21.567

(57) ABSTRACT

The invention provides advances in the arts with useful and novel methods for assembling multi-layer semiconductor structures having one or more internal conductive layers. The disclosed structures provide advantages in terms of resistance to Single Event Effects (SEE) particularly useful in electronics designed for radiation hardness. Disclosed methods include steps for providing two semiconductor layers, each having a conductive surface, and bonding them together with their conductive surfaces adjoining in order to form an internal conductive layer within a completed multi-layer structure. The conductive surfaces may include metals selected for their superior conductivity, refractory metals, selected primarily for their heat-resistance, or conductive dopants. In alternative embodiments, vertical interconnects are also included.

### PRIORITY ENTITLEMENT

This application is entitled to priority based on Provisional Patent Application Ser. No. 61/377,903 filed on Aug. 27, 2010, which is incorporated herein for all purposes by this reference. This application and the Provisional Patent Application have at least one common inventor.

### TECHNICAL FIELD

The invention relates to integrated circuits (ICs) and semiconductor wafers for the manufacture of ICs. More particularly, the invention relates to multi-layer wafer and IC structures having one or more conductive layer incorporated within a semiconductor substrate.

### BACKGROUND OF THE INVENTION

Space and military applications place high demands on the robustness and reliability of Integrated Circuits (ICs). Single Event Effects (SEE), in which high energy particles create localized charges within the IC, can lead to signal errors and, in extreme cases, system failure. It is desirable to reduce the susceptibility of ICs to SEEs. Single Event Effects are caused by the intrusion into the device of a single energetic particle, and can take many forms. A single event upset (SEU) is a change of state in a microelectronic device such as a memory cell, transistor, or other semiconductor device which can be caused by the intrusion of extraneous ions or electro-magnetic radiation into the device. In the event a free charge caused by the ionization contacts, or comes sufficiently close to, the physical structure of a logic element, the charge of the element can be changed. This type of spurious charge can give rise to a change in the device output or operation resulting in an SEU, or a soft error, a change in state alone that is not physically damaging to the device. Several types of potentially destructive hard errors can occur as a result of the intrusion of higher energy particles into a device. Single Event Latchup (SEL) results in a high operating current, above device specifications, and must be cleared by a power reset. In extreme cases, the device can be permanently damaged.

Radiation effects represent a significant threat to the robustness and reliability of integrated circuits (IC) in military and space applications in particular. While significant effort has been expended to understand the fundamental physical mechanisms leading to radiation damage, practical approaches to improve the radiation hardness of integrated circuits through available manufacturing techniques are being sought. A common approach to reducing SEE sensitivity in microelectronics includes manufacturing integrated circuits on a silicon wafer having a buried oxide insulating layer. While this approach can help to limit the amount of SEE charge which reaches active IC devices, it introduces significant design complexity, manufacturing complexity, and increased cost. Moreover, this technique is not readily adaptable to implementation with standard bulk silicon IC manufacturing processes.

One approach to reducing the susceptibility of ICs to SEU, SEL, and other SEE hazards is to reduce the substrate-to-ground resistance by altering the starting wafer material. In advanced silicon processes, it is known to start the manufacturing process with a highly doped p-type wafer substrate upon which a lightly doped p-type epitaxial layer of one to several microns thick is grown. For a given radiation charge event, a lower substrate resistance yields less incremental voltage in the p-type substrate layer local to the NMOS transistor. This highly doped substrate provides a low resistance path to ground and substantially reduces the occurrence of Single Event Effects.

Another known design approach to reduce the susceptibility of ICs to upset and latchup radiation effects is to form the transistors on a silicon-on-insulator (SOI) wafer. Creating the transistors directly above a buried layer of insulating silicon dioxide eliminates the parasitic bipolar transistors which lead to latchup. Another advantage of SOI circuit designs is the dramatic reduction in the silicon volume and junction areas which collect charge during a heavy ion single event. While SOI offers improved radiation robustness, the use of SOI techniques is hampered by the limitations of standard manufacturing processes. In such devices, the silicon film thickness is critical to controlling SEU sensitivity. Reduced thickness yields less silicon volume available for the creation of SEU charge at the expense of increasing bipolar gain of partially depleted SOI. Fully depleted SOI offers the most significant radiation hardness capability but is the most difficult to manufacture since it requires extremely tight tolerances to ensure silicon film thickness and doping uniformity. SOI also presents additional design challenges because of floating body and hysteresis effects.

Due to the foregoing and other problems and potential advantages, improved semiconductor substrate designs and associated methods would be a useful contribution to the applicable arts.

### SUMMARY OF THE INVENTION

In carrying out the principles of the present invention, in accordance with preferred embodiments, useful and advantageous innovations have been developed to greatly reduce, and in many cases, effectively eliminate the sensitivity of integrated circuits to latchup failures and to significantly reduce the occurrence of soft error failures. The present disclosure describes presently preferred examples of steps devised to form one or more internal conductive layer within a multi-layer semiconductor wafer or IC using standard commercial silicon or gallium arsenide manufacturing processes. All possible variations within the scope of the invention cannot, and need not, be shown. It should be understood that the invention may be used with various conductive materials and various substrate materials, IC, and package formats.

According to one aspect of the invention, in examples of preferred embodiments, methods for assembling multi-layer semiconductor structures include steps for providing two semiconductor layers each having a conductive surface and bonding them together with their conductive surfaces adjoining in order to form an internal conductive layer within a completed multi-layer structure.

According to another aspect of the invention, a preferred embodiment of a method for assembling a multi-layer semiconductor structure having an internal conductive layer includes using at least one component layer having a conductive refractory metal surface selected from the group; cobalt, ruthenium, tantalum, tantalum nitride, indium oxide, tungsten nitride, titanium nitride, tungsten, titanium, platinum, and nickel.

According to another aspect of the invention, a preferred embodiment of a method for assembling a multi-layer semiconductor structure having an internal conductive layer includes using at least one component layer having a conductor-doped surface with a dopant selected from the group; arsenic, phosphorus, boron, antimony.

According to another aspect of the invention, a preferred embodiment of a method for assembling a multi-layer semiconductor structure having an internal conductive layer includes using at least one component layer having a conductive metal surface having metal selected from the group; gold, copper, aluminum.

According to another aspect of the invention, a preferred embodiment of a method for assembling a multi-layer semiconductor structure having an internal conductive layer includes steps for providing more than one internal conductive layer.

According to another aspect of the invention, a preferred embodiment of a method for assembling a multi-layer semiconductor structure having an internal conductive layer includes the step of encircling an internal conductive layer with an insulator.

According to another aspect of the invention, a preferred embodiment of a method for assembling a multi-layer semiconductor structure having an internal conductive layer includes the step of providing a plurality of vertical electrical paths between an internal conductive layer and a non-adjoining layer.

According to another aspect of the invention, a preferred embodiment of a method for assembling a multi-layer semiconductor structure having an internal conductive layer includes the step of providing a plurality of Through-Silicon-Via vertical electrical paths between an internal conductive layer and a non-adjoining layer.

According to another aspect of the invention, a preferred embodiment of a method for assembling a multi-layer semiconductor structure having an internal conductive layer includes the step of providing an electrical path between an internal conductive layer and a ground terminal.

According to another aspect of the invention, a preferred embodiment of a method for assembling a multi-layer semiconductor structure having an internal conductive layer includes the step of removing selected portions of an internal conductive layer.

According to another aspect of the invention, a preferred embodiment of a method for assembling a multi-layer semiconductor structure having an internal conductive layer includes the step of removing selected portions of an internal conductive layer and replacing the removed portions with insulating material.

According to another aspect of the invention, a preferred embodiment of a method for assembling a multi-layer semiconductor structure having an internal conductive layer includes steps forming a box shield around a selected location.

The invention has advantages including but not limited to providing one or more of; improved SEE hardness, and reduced costs. These and other advantageous, features, and benefits of the invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the description and drawings in which:

FIG. 1A is an exploded cutaway partial side view of an example of an embodiment of a multi-layer structure according to the preferred methods of the invention;

FIG. 1B is a cutaway partial side view of an example of an embodiment of a multi-layer structure according to the preferred methods of the invention;

FIG. 2 is a cutaway partial side view of an example of an embodiment of a multi-layer IC structure according to preferred methods of the invention;

FIG. 3 is a cutaway partial side view of an example of an embodiment of a multi-layer wafer structure according to preferred methods of the invention;

FIG. 4 depicts a cutaway partial side view of an example of an embodiment of a multi-layer IC structure assembled according to preferred methods of the invention subjected to high energy particle intrusion;

FIG. 5 is a cutaway partial side view of an example of another embodiment of a multi-layer IC structure according to preferred methods of the invention; and

FIG. 6 is a cutaway partial side view of an example of another embodiment of a multi-layer IC structure according to preferred methods of the invention.

References in the detailed description correspond to like references in the various drawings unless otherwise noted. Descriptive and directional terms used in the written description such as front, back, top, bottom, upper, side, et cetera, refer to the drawings themselves as laid out on the paper and not to physical limitations of the invention unless specifically noted. The drawings are not to scale, and some features of embodiments shown and discussed are simplified or amplified for illustrating principles and features as well as anticipated and unanticipated advantages of the invention.

### DESCRIPTION OF PREFERRED EMBODIMENTS

The making and using of various specific exemplary embodiments of the invention are discussed herein. It should be appreciated that the systems and methods described and shown exemplify inventive concepts which can be embodied in a wide variety of specific contexts. It should also be understood that the invention may be practiced in various applications and embodiments without altering the principles of the invention. For purposes of clarity, detailed descriptions of functions, components, and systems familiar to those skilled in the applicable arts are not included. In general, the invention provides multi-layer semiconductor wafer, substrates, and ICs having one or more subsurface conductive layer. The invention is described in the context of representative exemplary embodiments. Although variations in the details of the embodiments are possible, each has advantages over the prior art.

Wafer bonding is known to some extent as a technique for forming buried insulating layers within a silicon wafer. In this process, two wafers each have a surface coated with a thin oxide of silicon, selected for its insulating properties. The coated surfaces are brought together and bonded using a combination of pressure and temperature to form a single multi-layer wafer. Once joined, one side of the multi-layer wafer is polished back to create a thin layer of silicon on top of the multi-layer silicon wafer containing a buried insulating layer within. Through their efforts, the inventors have developed methods for forming conductive layers within multi-layer semiconductors by bonding variously prepared wafers together. The internal conductive layer(s) thus formed may be used as a shield to protect selected areas from SEEs, for low-resistance connections underneath the active transistors within an IC, and for similar purposes.

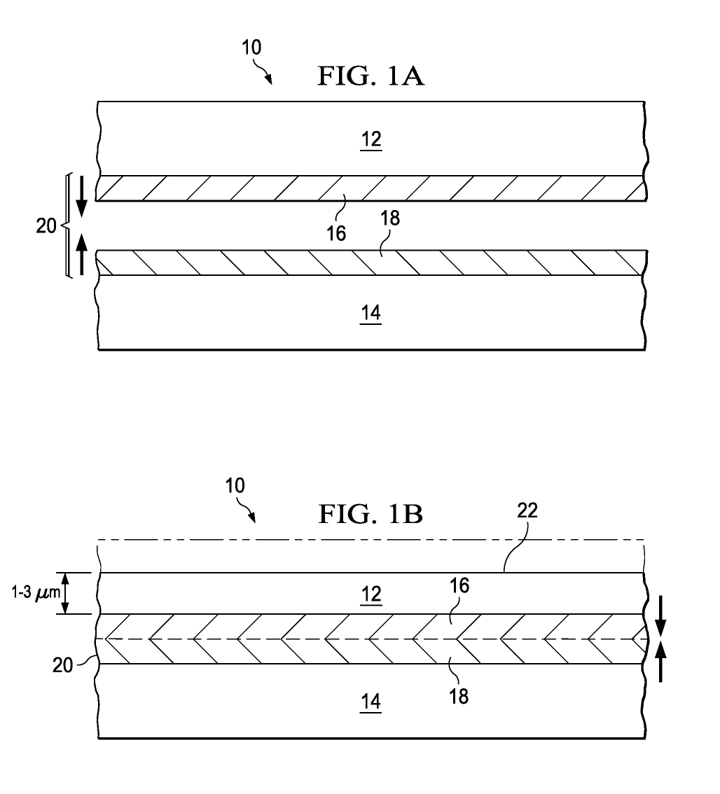

Referring initially to FIG. 1A, an exemplary illustration of steps in methods for the formation of an internal conductive layer within a multi-layer structure 10 through wafer bonding is shown in an exploded partial cross section view. Two separate silicon wafers, herein denominated “layers” 12, 14, to prevent confusion with completed multi-layer assemblies 10, are provided. Conductive metal layers 16, 18 are deposited on a surface of each of the two respective layers 12, 14. Subsequent to the conductive 16, 18 layer creation, the component handle layer 12 and substrate layer 14 are brought into contact with their conductive surfaces 16, 18 adjoining. The layers 12, 14 are fused together using a combination of temperature and pressure sufficient to create a strongly bonded internal conductive layer 20 at the junction of the conductive surfaces 16, 18. The resulting multi-layer wafer 10 may then be further processed into numerous multi-layer ICs or other devices. Preferably, the conductive surfaces 16, 18 are comprised of metals selected for their conductivity, such as gold, copper, aluminum. Refractory metals may also be used, selected for their conductivity, heat resistance, and density, such as cobalt, ruthenium, tantalum, tantalum nitride, indium oxide, tungsten nitride, titanium nitride, tungsten, titanium, platinum, and nickel. Surfaces doped with arsenic, phosphorus, boron, antimony may also be used. The substrate layers 12, 14, are preferably silicon or gallium arsenide materials as used in common semiconductor processing, although more exotic materials may also be used.

Now referring primarily to FIG. 1B, a cross-section of the resulting bonded multi-layer structure 10 is depicted following the preferred step of thinning of the top substrate layer 12 prior to IC processing. This decreases the distance between the internal conductive layer 20 and the top surface 22 of the substrate layer 12, upon which additional circuitry may then preferably be constructed.

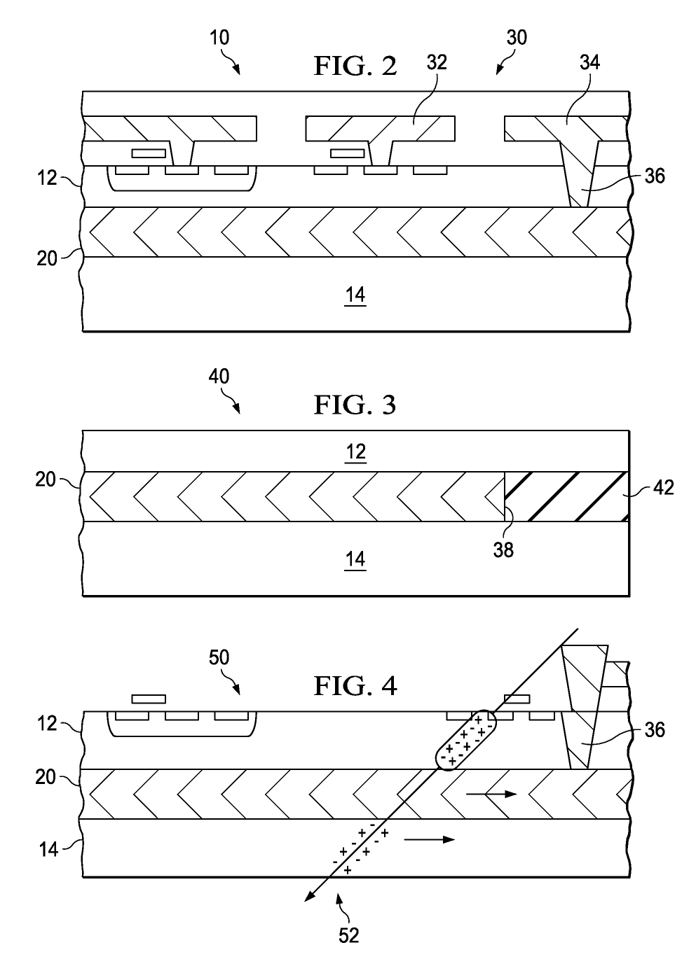

FIG. 2 shows a partial cross-section of an IC 30 constructed on a multi-layer wafer 10. As shown, IC features such as transistors 32, other components and interconnections 34 may be formed on the substrate 12, preferably using standard semiconductor device processing techniques, materials, and equipment. Through-Silicon-Via (TSV) manufacturing techniques are also preferably employed to connect the internal conductive layer 20 to other circuitry contained on the IC, e.g. 34, using TSVs 36. Such vertical connections may be used to make connections among IC circuits, or to provide ground connections. Alternatively, other low-impedance connection techniques may also be used, such as deep silicon vias.

FIG. 3 shows a partial cross-section of a preferred embodiment of a multi-layer wafer 40 according to invention. The edge 38 of the internal conductive layer 20 is illustrated with a cap 42 formed using silicon oxide, or other insulating material. Preferably, this cap 42 provides a barrier protecting the conductive layer 20 from the ambient air in order to mitigate outgassing. Another advantage of this feature is the limitation of contamination of IC semiconductor processing equipment in a standard IC manufacturing process. The edge barrier 42 also provides electrical isolation between the internal conductor 20 and any external conductors that might come in contact with the assembly 40 such as conductive die attach epoxy or similar material that may have a tendency to wick up the sides of the die, for example, potentially causing a short to the internal conductive layer 20 and external contacts.

The invented methods for providing internal conductive layers within multi-layer semiconductor wafer structures offers advantages for microelectronics in general, and for radiation hardened microelectronics in particular. A cross section of a multi-layer semiconductor IC device 50 having an internal conductive layer 20 is shown in FIG. 4. The intrusion of a high energy particle 52 (not part of the invention) is shown. Electron-hole pair creation by the high energy particle 52 is represented by the “+” and “−”. Because it offers an extremely low resistance path, the internal conductive layer 20, preferably having a sheet resistance on the order of about 2 ohms/square or lower, can effectively eliminate latchup. For thin epitaxial layers present in advanced CMOS technologies, the inclusion of an internal conductive layer also has the potential to reduce prompt dose upset rates compared to its standard bulk/epi counterpart. In some preferred embodiments, the inventive convergence of Through Silicon Via (TSV) technology integrated with metalized, or silicided, wafer bonding techniques makes this practical. Incorporating conducting layers into the starting layers of standard bulk/epi integrated circuits offers advantageous improvements to existing commercial IC manufacturing processes, reducing costs associated with radiation hardening. In addition, the latchup resistance of commercially available integrated circuits can also be improved using the multi-layer structure of the inventions. The technology may also be used to provide similar benefits in radio frequency and side channel reduction in appropriate applications.

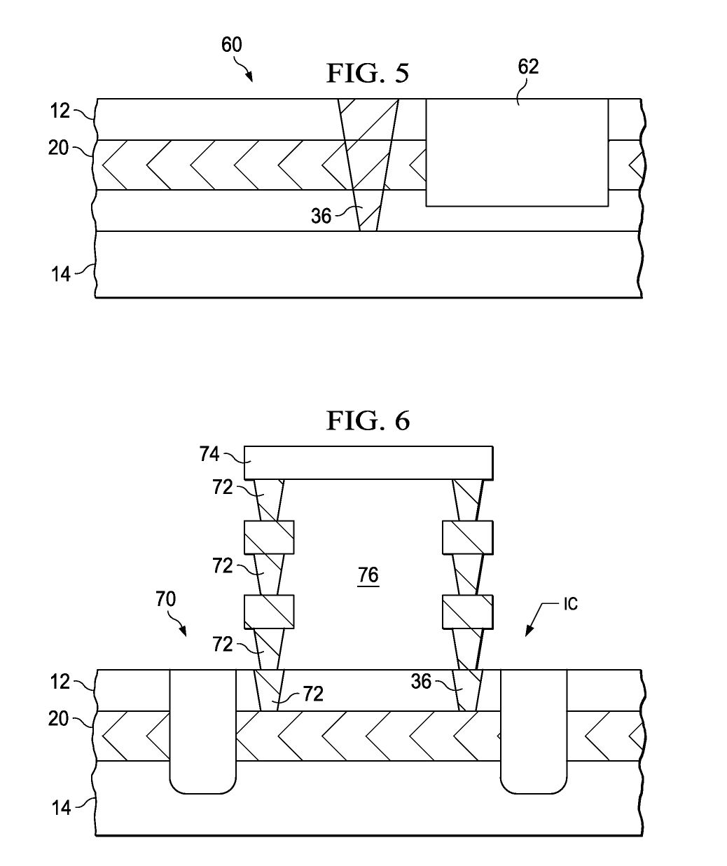

FIG. 5 portrays a cross-section of an alternative embodiment of a multi-layer structure 60 according to the invention having an internal conductive layer 20 in which the internal conductive layer 20 has been selectively removed and replaced with an insulator 62. Such steps may be preferable for implementation under integrated passive components such as inductors, for example. Other implementations of patterning or selectively removing the internal conductive layer are also possible. This reduces substrate resistance parasitics which can degrade the quality factor of high frequency inductors and capacitors.

FIG. 6 shows an implementation of a multi-layer structure 70 in which the internal conductive layer 20 is electrically coupled using vertical connectors 72 of conductive material, such as metal, to a parallel top conductor 74 surrounding a component 76 or components in the active region of a device. Surrounding a component 76 or components within a conducting cage 78 in this manner can be used to shield circuitry, e.g., 76, from noise or emissions of other circuits located on the IC. One potential advantage to this embodiment is to enable denser integration of noise-sensitive circuitry such as radio frequency (RF) low noise amplifiers with standard mixed signal or digital circuitry on the same IC chip, e.g., 70. A conductive cage structure can also be used to create microelectromechanical system (MEMS) components such as RF tuning forks, accelerometers and the like. This novel method for including an internal conductive layer improves the radiation hardness of integrated circuits. This technology has the potential for ready integration into standard semiconductor integrated circuit manufacturing processes and to substantially reduce the susceptibility of ICs to prompt dose latchup. It should be appreciated by those skilled in the arts that multiple internal conductive layers may also be used in multi-layer structures within the scope of the invention.

The methods of the invention, and associated structures, provide one or more advantages. Some of the potential advantages of internal conductive layers in multi-layer structures include their use to retard the diffusion of dopant atoms within a semiconductor wafer, or to provide a thermal mass to transfer heat away from localized areas within a device assembly. By applying a current, an internal conductive layer formed into a resistor may be used as a heating element to assist in thermo-chemical reactions or fluid/air transfer within or to/from a semiconductor die. An internal conductive layer formed from two different, adjacent metals may be used to form a Seebeck element to generate a known electrical potential from differences in temperature across a chip. This technique may be used, in conjunction with known IC circuit design techniques, to assist in efficient power management across a chip. An internal conductive layer may also be used in combination with adjacent hollow substrate cavities to create a piezo-electric element to transport and/or receive air, fluids, and acoustic information. While the invention has been described with reference to certain illustrative embodiments, those described herein are not intended to be construed in a limiting sense. For example, variations or combinations of steps or materials in the embodiments shown and described may be used in particular cases without departure from the invention. Although the presently preferred embodiments are described herein in terms of particular examples, modifications and combinations of the illustrative embodiments as well as other advantages and embodiments of the invention will be apparent to persons skilled in the arts upon reference to the drawings, description, and claims.

We claim:

1. A method for assembling a multi-layer semiconductor wafer comprising:
providing a semiconductor substrate layer having a conductive surface;
providing a handle layer having a conductive surface; and
bonding the semiconductor substrate layer with the handle layer wherein the conductive surfaces adjoin to form an internal conductive layer within a completed multi-layer semiconductor wafer.

2. The method for assembling a multi-layer semiconductor wafer according to claim 1 wherein at least one of the conductive surfaces comprises a refractory metal selected from the group; cobalt, ruthenium, tantalum, tantalum nitride, indium oxide, tungsten nitride, titanium nitride, tungsten, titanium, platinum, and nickel.

3. The method for assembling a multi-layer semiconductor wafer according to claim 1 wherein at least one of the layers comprises silicon.

4. The method for assembling a multi-layer semiconductor wafer according to claim 1 wherein at least one of the layers comprises gallium arsenide.

5. The method for assembling a multi-layer semiconductor wafer according to claim 1 wherein at least one of the conductive surfaces comprises a dopant selected from the group; arsenic, phosphorus, boron, antimony.

6. The method for assembling a multi-layer semiconductor wafer according to claim 1 wherein at least one of the conductive surfaces comprises a metal selected from the group; gold, copper, aluminum.

7. The method for assembling a multi-layer semiconductor wafer according to claim 1 further comprising the steps of:
providing a second semiconductor substrate layer having a conductive surface;
providing a second handle layer having a conductive surface; and
bonding the second semiconductor substrate layer with the second handle layer wherein the conductive surfaces adjoin to form a second internal conductive layer.

8. The method for assembling a multi-layer semiconductor wafer according to claim 1 further comprising the step of encircling an internal conductive layer with an insulator.

9. The method for assembling a multi-layer semiconductor wafer according to claim 1 further comprising the step of providing a plurality of vertical electrical paths between an internal conductive layer and a non-adjoining layer.

10. The method for assembling a multi-layer semiconductor wafer according to claim 1 further comprising the step of providing a plurality of Through-Silicon-Via vertical electrical paths between an internal conductive layer and a non-adjoining layer.

11. The method for assembling a multi-layer semiconductor wafer according to claim 1 further comprising the step of providing an electrical path between an internal conductive layer and a ground terminal.

12. The method for assembling a multi-layer semiconductor wafer according to claim 1 further comprising the step of removing selected portions of an internal conductive layer.

13. The method for assembling a multi-layer semiconductor wafer according to claim 1 further comprising the step of removing selected portions of an internal conductive layer and replacing the removed portions with insulating material.

14. The method for assembling a multi-layer semiconductor wafer according to claim 1 further comprising the step of providing a plurality of vertical electrical paths between an internal conductive layer and a non-adjoining layer, and thereby forming a box shield around a selected location.

15. A method for assembling a multi-layer IC comprising:
providing a semiconductor substrate having a conductive surface;
providing a handle layer having a conductive surface;
bonding the semiconductor substrate with the handle layer wherein the conductive surfaces adjoin to form an internal conductive layer within a multi-layer substrate assembly; and
forming an integrated circuit on a surface of the multi-layer substrate assembly.

16. The method for assembling a multi-layer IC according to claim 15 wherein at least one of the conductive surfaces comprises a refractory metal selected from the group; cobalt, ruthenium, tantalum, tantalum nitride, indium oxide, tungsten nitride, titanium nitride, tungsten, titanium, platinum, and nickel.

17. The method for assembling a multi-layer IC according to claim 15 wherein at least one of the conductive surfaces comprises a dopant selected from the group; arsenic, phosphorus, boron, antimony.

18. The method for assembling a multi-layer IC according to claim 15 wherein at least one of the conductive surfaces comprises a metal selected from the group;
gold, copper, aluminum.

19. The method for assembling a multi-layer semiconductor wafer according to claim 15 further comprising the steps of:
providing a second semiconductor substrate having a conductive surface;
providing a second handle layer having a conductive surface; and
bonding the second semiconductor substrate with the second handle layer wherein the conductive surfaces adjoin to form a second internal conductive layer.

20. The method for assembling a multi-layer IC according to claim 15 further comprising the step of encircling an internal conductive layer with an insulator.

21. The method for assembling a multi-layer IC according to claim 15 further comprising the step of providing a plurality of vertical electrical paths between an internal conductive layer and a non-adjoining layer.

22. The method for assembling a multi-layer IC according to claim 15 further comprising the step of providing a plurality of Through-Silicon-Via vertical electrical paths between an internal conductive layer and a non-adjoining layer.

23. The method for assembling a multi-layer IC according to claim 15 further comprising the step of providing an electrical path between an internal conductive layer and a ground terminal.

24. The method for assembling a multi-layer IC according to claim 15 further comprising the step of removing selected portions of an internal conductive layer.

25. The method for assembling a multi-layer IC according to claim 15 further comprising the step of removing selected portions of an internal conductive layer and replacing the removed portions with insulating material.

26. The method for assembling a multi-layer IC according to claim 15 further comprising the step of providing a plurality of vertical electrical paths between an internal conductive layer and a non-adjoining layer, thereby forming a box shield around a selected location.
